(19) United States
(12) Patent Application Publication
(10) Pub. No.: US 2006/0157723 A1
(43) Pub. Date: Jul. 20, 2006

(54) Light emitting device

(76) Inventors: John Douglas Lambkin, County Cork (IE); Thomas David McCormack, Dublin (IE)

Correspondence Address: LAW OFFICES OF;JACOBSON HOLMAN, PROFESSIONAL LIMITED LIABILITY COMPANY, 400 SEVENTH STREET, N.W., WASHINGTON, DC, 20004, US

(21) Appl. No.: 11/300,518

(22) Filed: Dec. 15, 2005

Related U.S. Application Data
(63) Continuation of application No. PCT/IE04/00085, filed on Jun. 7, 2004.

(30) Foreign Application Priority Data
Aug. 19, 2003 (IE) IE 2003/0457
Jul. 23, 2003 (IE) IE 2003/0543

(51) Int. Cl. H01L 33/00

(52) U.S. Cl. 257/98

(57) ABSTRACT

A light emitting device has a resonant cavity LED (RCLED) (1) within encapsulation (24). The encapsulation has a convex spherical surface (26) forming a lens for emitted light. The diode's cavity (14, 15, 16) is of a length to provide detuning of 20 nm for an emission wavelength of 650 nm. A relatively flat thermal response is achieved.

### INTRODUCTION

1. Field of the Invention

The invention relates to light emitting diodes of the resonant cavity type (RCLEDs), and devices incorporating such diodes.

2. Prior Art Discussion

Plastic optical fibre (POF) and large core plastic clad silica (PCS) fibre have been used for many years for relatively low data rate communication applications, particularly in industrial automation applications. In this instance the use of POF and PCS fibre enable low cost optical fibre links to be established in high electromagnetic interference (EMI) environments without resorting to more costly glass fibre links. The large cores of step-index plastic optical fibre (SI-POF) and polymer-clad silica (PCS) fibre and the ability to use low-cost plastic-moulded connectors gives a significant cost advantage when compared to more conventional multi-mode glass fibre alternatives.

Due to the chemical nature of the atomic bonds of polymethylmethacrylate (PMMA), the polymer used to fabricate SI-POF, one of several attenuation windows in the POF occurs at 650 nm with an attenuation of approximately −180 dB/km. As efficient light emitting devices with an output wavelength to match the 650 nm window can be fabricated using the group III-V compound semiconductor AlGaInP grown on GaAs substrates, 650 nm has become the de facto wavelength standard for POF links. Industrial automation POF communication links conforming to standards such as SERCOS, Profibus and Interbus-S operate at relatively low bit rates of 1-16 Mbps and use prior art low cost light emitting diodes (LEDs) operating at 650 nm within the emitter transceiver components. However within a number of new standards such as the automotive data buses MoST and IDB-1394 and the consumer bus IEEE-1394 there now exist specifications for data rates of hundreds of Mbps over 50 m of SI-POF. To achieve the bit rates in the range 50-250 Mbps it is increasingly common to replace conventional surface emitting LEDs with Resonant Cavity Light Emitting Diodes (RCLEDs).

An RCLED is a diode placed between two mirrors, typically fabricated from layers of alternating refractive index. Currently, POF transceivers used in consumer, industrial and automotive applications are limited to the range from −40° C. to 85° C. However for use in high temperature applications such as brake-by-wire or drive-by-wire there is a need to extend this range to approximately 105° C. in the short term and ultimately to approximately 125° C. in the medium to longer term.

A disadvantage of RCLEDs operating in the visible portion of the spectrum is their sensitivity to temperature. A visible emitting RCLED will in general display a large and non-linear temperature dependence of its output power above temperatures of −40° C. Fig. A shows the variation of the optical power coupled into a SI-POF (NA 0.5) of a typical prior art plastic encapsulated 650 nm RCLED as a function of continuous wave (CW) drive current and ambient temperature. At a drive current of 30 mA the total change in POF coupled power between −40° C. to 85° C. is 8 dB which is unacceptably large for high temperature applications such as MOST and IDB-1394 as the POF coupled power at elevated temperatures will drop below the specified minimum values as fixed by the standards.

It is possible to reduce the thermal sensitivity of RCLEDs by carefully detuning the device. Detuning is defined as the difference between the cavity resonance wavelength (sometimes called the Fabry-Perot wavelength) and the peak of the emission from the active region. It is positive when the Fabry-Perot (FP) wavelength is longer than the active region emission wavelength. In practice this is achieved by setting the total optical path length of the cavity to be a pre-determined extent greater than the wavelength of the light emitted by the active region. It is important to determine the optimum detuning for a RCLED bearing in mind the required specifications of the device and particular application.

The paper Wirth R et al: “High-efficiency RCLEDs emitting at 650 nm” Photonics Technology Letters, 2001, vol. 13; pages 421-423 describes RCLEDs emitting at 650 nm. This document mentions epoxy encapsulation of the RCLED, and a detuning of 15 nm.

The invention is therefore directed towards providing a RCLED which:

has a weak response to temperature change, and/or

has a high optical efficiency, and/or

has improved coupling efficiency to POF and PCS.

### SUMMARY OF THE INVENTION

According to the invention there is provided a light emitting device comprising a resonant cavity light emitting diode comprising an active region in a cavity also comprising confinement layers, and resonant mirrors, and wherein the optical length of the cavity exceeds the active region emitting wavelength by a distance determined by a detuning value characterised in that,
the detuning value is the range of 2.7% to 3.4% of the emitting wavelength; and
the device further comprises an encapsulant around at least the emitting side of the diode, said encapsulant comprising a convex surface forming a lens in alignment with the diode.

In one embodiment, the emitting wavelength is approximately 650 nm and the detuning is 18 nm to 22 nm.

In another embodiment, the detuning value is approximately 20 nm.

In a further embodiment, the lens has a spherical surface.

In one embodiment, the radius of curvature of the lens is 0.3 mm to 0.5 mm.

In another embodiment, the radius of curvature is approximately 0.35 mm.

In a further embodiment, the depth of encapsulation between the diode and the top of the lens is in the range of 0.4 mm to 0.8 mm.

In one embodiment, the depth is approximately 0.64 mm.

In another embodiment, the active region comprises quantum wells with a width less than or equal to 8.0 nm.

In a further embodiment, there are in the range of 1 to 4 quantum wells in the active region.

In one embodiment, the encapsulant is of a material having a refractive index higher than that of air and lower than that of the mirror at the emitting end of the diode.

In another embodiment, the encapsulant material is PMMA.

In a further embodiment, the encapsulant forms a socket to receive a fibre waveguide for transmission of light from the waveguide.

### DETAILED DESCRIPTION OF THE INVENTION

### BRIEF DESCRIPTION OF THE DRAWINGS

The invention will be more clearly understood from the following description of some embodiments thereof, given by way of example only with reference to the accompanying drawings in which:

FIG. 1 is a perspective diagram of a diode of the invention;

FIG. 2 is a diagrammatic cross-sectional view of the diode when packaged;

FIG. 3 is a plot illustrating different optimum detaining into air and PMMA; and

FIG. 4 is a plot for light out as a function of current for an RCLED of the invention.

### DESCRIPTION OF THE EMBODIMENTS

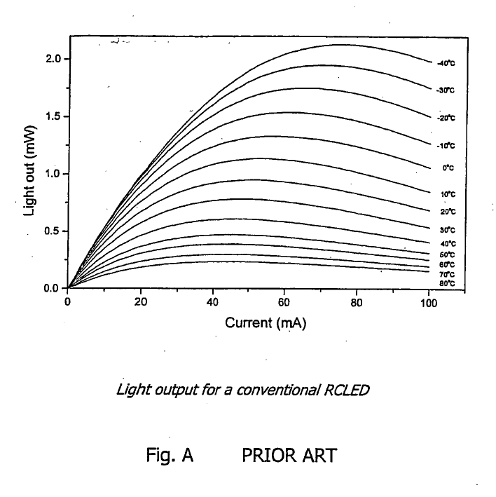

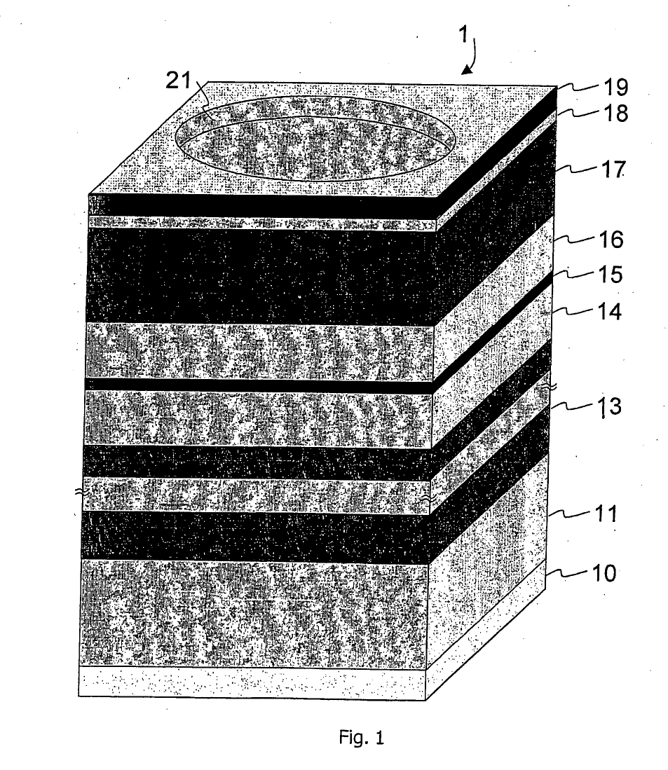

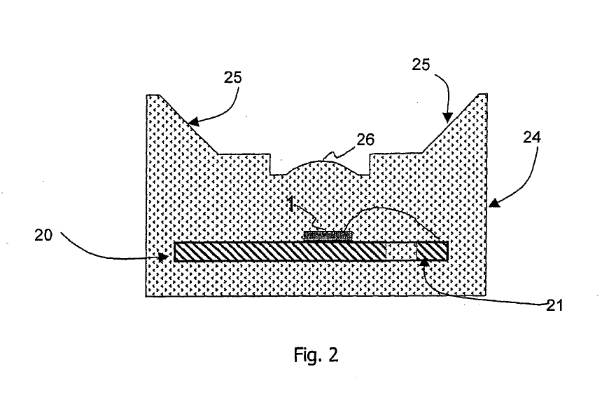

Referring to FIG. 1, a diagrammatic representation of an RCLED is shown, and FIG. 2 shows the device as it would appear on the lead frame and in the encapsulating medium. The RCLED 1 comprises a bottom electrode 10, substrate material 11, a bottom mirror 13 formed by a multilayer distributed Bragg reflector (DBR) with reflectivity R_{A}>99%, a lower confining layer 14 of a certain conductivity, an active region 15, an upper confining layer 16 of the opposite type of conductivity to the lower confining layer 14. There is also a second mirror 17 (also called the “output” mirror) formed by a multilayer distributed Bragg reflector (DBR) with reflectivity R_{B}<R_{A}, a current spreading layer 18, and a highly doped contact layer 19 with a centrally located light output aperture 21.

Referring to FIG. 2 the RCLED is mounted on a lead frame 20 at a cathode section and is wire bonded to an anode section 21 of the lead frame. Of course, the anode/cathode arrangement may be reversed as will be appreciated by those skilled in the art. The RCLED 1 and the lead frame 20 are surrounded by encapsulation 24 of PMMA material forming a rim or socket 25 for receiving a fibre waveguide. The encapsulation 24 also includes a convex spherical lens 26 with a radius of 0.35 mm in alignment with the RCLED 1. The distance between the top of the diode 1 and the top of the lens 26 is 0.64 mm. This parameter is more generally preferably in the range of 0.3 mm to 8.0 mm for a radius of curvature of 0.18 to 0.42 mm. Over this range the exact relationship between the lens radius and the distance to the lens is given by R(in mm)=0.4819×(distance to lens in mm)+0.0388.

The substrate 11 is a heavily doped n-type III-V or II-VI semiconductor, such as GaAs, with a thickness of 500 μm, and generally preferably in the range of 100 μm to 700 μm. The quarter wave stack is composed of a plurality of pairs (or periods) of semiconductor layers forming a multi-layer bottom DBR, with alternating values of high and low refractive index. The number of pairs is 38 and is more generally preferably in the range of 32-40. The thickness of each layer in the pair is λ_{SE}/4n, wherein λ_{SE} is the wavelength of the spontaneous emission of the active region (in this case 650 nm) and n the refractive index. It is important that the refractive index contrast and the total number of mirror pairs is such that the reflectivity of the bottom DBR is greater than that of the output DBR i.e. R_{B}<R_{A}. The active region 15 and the bottom and top confining layers 14 and 16 define the total length of the cavity. The optical length of the cavity is a low integer multiple of (λ_{SE}+detuning)/2 and thus the thickness of the confining layers is selected on this basis.

The active region 15 is where spontaneous emission of light takes place under the proper bias. In this embodiment the active region 15 is comprised of a quantum well structure formed by a narrow band-gap semiconductor confined by wide band-gap semiconductor. The number of quantum wells (QWs) is 3, and is more generally in the range of 1 to 4. The width of each QW is 8 nm and is generally less than or equal to 8 nm.

Compared to the bottom DBR the top DBR is comprised of a lower number of pairs. It has 6 pairs, and this number is generally in the range of 4 to 8. The top DBR has a lower refractive index contrast to ensure that R_{B}<R_{A}. This is capped with a thick current spreading layer of 14 nm thickness, preferably in the range 10-100 nm thick, and then a contact layer whose thickness is 20 nm, and is preferably in the range 10-100 nm.

One of the aspects of the invention is minimisation of the temperature response by balancing the various temperature related effects. The temperature dependence is attributable to several factors:
1 λ_{SE} increases with temperature which alters the detuning which in turn affects the extraction efficiency.
2 The QW emission broadening reduces the extraction efficiency.
3 Leakage and non-radiative recombination are thermally enhanced.

The detuning is selected such that the optimum detuning in terms of extraction efficiency occurs in the middle of the required temperature range. This helps to lessen the overall temperature sensitivity.

The exact thicknesses of the layers forming the cavity and quantum well layers together with the detuning and the total number of mirror pairs in the Bragg mirror are chosen to maximise the coupling efficiency either into a total solid angle of 2π or into the acceptance angle of a fibre. It has been found that the maximum coupling efficiency into step-index POF with a numerical aperture of 0.5 is achieved with the number of Bragg pairs being no greater than 8.

The cavity detuning is (for a 650 nm emitting wavelength and at room temperature) within the range of 18 nm to 22 nm and in this embodiment 20. More generally, this may be expressed as 2.7% to 3.4% of the emitting wavelength. This is larger than in prior art devices. It is to be noted that detuning changes with temperature, as emission wavelength changes with temperature. Hence, the value range is given for room temperature.

At a given temperature the detuning is chosen to maximise the extraction efficiency which is defined as the ratio of the number of photons appearing in the final medium relative to the number generated in the active region. In a semi-conductor the extraction efficiency into air is limited by total internal reflection. For example, the critical angle between GaAs and air is 16.6° and thus rays incident at angles greater than this cannot escape. The total cone of light that can escape into air is only a fraction of what is generated in the active region. The critical angle from GaAs into PMMA is 26.3° and hence a much higher extraction efficiency is expected. However much of this light cannot escape into air for the same reasons as above and hence there is no advantage in terms of extraction efficiency in having PMMA as an intermediate medium when the final medium is air.

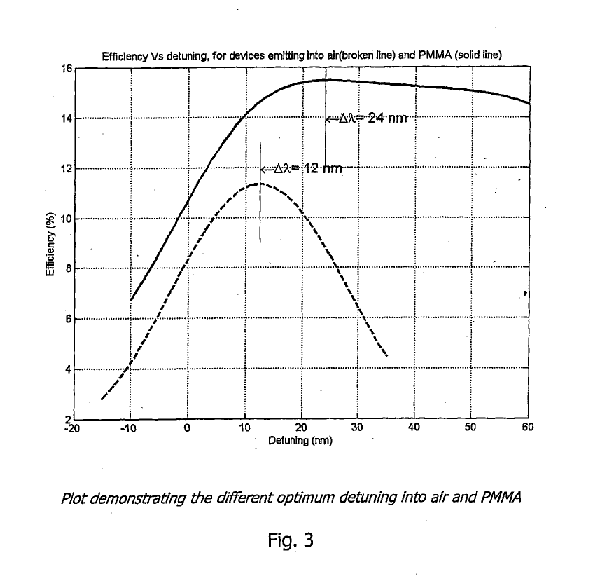

However critical angle considerations in going from PMMA to air can be ignored if the surface of the PMMA is curved in such a way as to minimise these effects. Consequently, a much larger detuning is provided to enhance the extraction efficiency, as can be seen in the results presented in FIG. 3.

The effects of the critical angle are minimised because the final surface is in the shape of a conicoid or asphere and in one particular embodiment forms a spherical convex lens 26 with a radius of 0.35 mm and with 0.64 mm of encapsulant between the top of the diode and the apex of the lens. This allows the light in the PMMA to be extracted with nearly 100% efficiency.

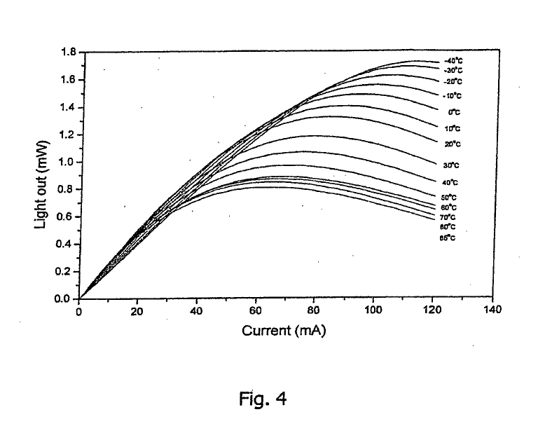

Operation of the RCLED based on an exemplary embodiment of these principles for the AlₓGaIn₁₋ₓP system is shown in FIG. 4 and should be compared with that of Fig. A which is for a conventional RCLED. Each of these figures is a plot of the light output versus drive current for temperatures in the range −40 to 80° C. For drive currents from 5-40 mA the light output is significantly more temperature stable for the RCLED according to this invention.

The invention is not limited to the embodiments described but may be varied in construction and detail. For example, the lens may have a different convex surface such as any conicoid or asphere. Where it is spherical, the radius may be different than described.

1-14. (canceled)

15. A light emitting device comprising a resonant cavity light emitting diode comprising an active region in a cavity also comprising confinement layers, and resonant mirrors, and wherein the optical length of the cavity exceeds the active region emitting wavelength by a distance determined by a detuning value, characterised in that,
the detuning value is the range of 2.7% to 3.4% of the emitting wavelength; and
the device further comprises an encapsulant around at least the emitting side of the diode, said encapsulant comprising a convex surface forming a lens in alignment with the diode.

16. The light emitting device as claimed in claim 15, wherein the emitting wavelength is approximately 650 nm and the detuning is 18 nm to 22 nm.

17. The light emitting device as claimed in claim 15, wherein the emitting wavelength is approximately 650 nm and the detuning value is approximately 20 nm.

18. The light emitting device as claimed in claim 15, wherein the lens has a spherical surface.

19. The light emitting device as claimed in claim 15, wherein the lens has a spherical surface; and wherein the radius of curvature of the lens is 0.3 mm to 0.5 mm.

20. The light emitting device as claimed in claim 19, wherein the radius of curvature is approximately 0.35 mm.

21. The light emitting device as claimed in claim 15, wherein the depth of encapsulation between the diode and the top of the lens is in the range of 0.4 mm to 0.8 mm.

22. The light emitting device as claimed in claim 21, wherein the depth is approximately 0.64 mm.

23. The light emitting device as claimed in claim 15, wherein the active region comprises quantum wells with a width less than or equal to 8.0 nm.

24. The light emitting device as claimed in claim 15, wherein there are in the range of 1 to 4 quantum wells in the active region.

25. The light emitting device as claimed in claim 15, wherein the encapsulant is of a material having a refractive index higher than that of air and lower than that of the mirror at the emitting end of the diode.

26. The light emitting device as claimed in claim 25, wherein the encapsulant material is PMMA.

27. The light emitting device as claimed in claim 15, wherein the encapsulant forms a socket to receive a fibre waveguide for transmission of light from the waveguide.
